(19) United States
(12) Patent Application Publication
(10) Pub. No.: US 2017/0239772 A1
(43) Pub. Date: Aug. 24, 2017

(54) RAMO4 SUBSTRATE AND MANUFACTURING METHOD THEREOF

(71) Applicant: Panasonic Intellectual Property Management Co., Ltd., Osaka (JP)

(72) Inventors: YOSHIFUMI TAKASU, Osaka (JP); YOSHIO OKAYAMA, Osaka (JP); AKIHIKO ISHIBASHI, Osaka (JP); ISAO TASHIRO, Osaka (JP); AKIO UETA, Hyogo (JP); MASAKI NOBUOKA, Nara (JP); NAOYA RYOKI, Osaka (JP)

(21) Appl. No.: 15/424,223

(22) Filed: Feb. 3, 2017

(30) Foreign Application Priority Data
Feb. 23, 2016 (JP) 2016-032349
Nov. 8, 2016 (JP) 2016-218197

(51) Int. Cl. B24B 7/22; C30B 33/00; C30B 29/22

(52) U.S. Cl. CPC B24B 7/22; C30B 29/22; C30B 33/00

(57) ABSTRACT

A RAMO₄ substrate includes a single crystal represented by a formula of RAMO₄ (in the formula, R indicates one or a plurality of trivalent elements selected from a group consisting of Sc, In, Y, and a lanthanoid element, A indicates one or a plurality of trivalent elements selected from a group consisting of Fe(III), Ga, and Al, and M indicates one or a plurality of bivalent elements selected from a group consisting of Mg, Mn, Fe(II), Co, Cu, Zn, and Cd). An epitaxially-grown surface is provided on at least one surface of the RAMO₄ substrate. An unevenness having a height of 500 nm or more is not provided on the epitaxially-grown surface.

### TECHNICAL FIELD

The technical field relates to a RAMO₄ substrate and a manufacturing method thereof.

### BACKGROUND

A RAMO₄ substrate is formed from single crystal represented by a formula of RAMO₄ (in the formula, R indicates one or a plurality of trivalent elements selected from a group consisting of Sc, In, Y, and a lanthanoid element, A indicates one or a plurality of trivalent elements selected from a group consisting of Fe(III), Ga, and Al, and M indicates one or a plurality of bivalent elements selected from a group consisting of Mg, Mn, Fe(II), Co, Cu, Zn, and Cd). As one of such a RAMO₄ substrate, a ScAlMgO₄ substrate is known. A ScAlMgO₄ substrate is used as a substrate for growing a nitride semiconductor such as GaN (see Japanese Patent Unexamined Publication No. 2015-178448, for example). FIG. 1 illustrates an example of a manufacturing method of a conventional ScAlMgO₄ substrate disclosed in Japanese Patent Unexamined Publication No. 2015-178448. The conventional ScAlMgO₄ substrate is manufactured by cleaving a ScAlMgO₄ bulk material.

### SUMMARY

However, it is difficult to obtain a RAMO₄ substrate having a desired surface shape, only by cleaving. Further, a substrate having higher quality is required. That is, an object of the disclosure is to provide a substrate having higher quality.

To solve the above object, as well as other concerns, according to the disclosure, a RAMO₄ substrate comprises a single crystal represented by a formula of RAMO₄ (in the formula, R indicates one or a plurality of trivalent elements selected from a group consisting of Sc, In, Y, and a lanthanoid element, A indicates one or a plurality of trivalent elements selected from a group consisting of Fe(III), Ga, and Al, and M indicates one or a plurality of bivalent elements selected from a group consisting of Mg, Mn, Fe(II), Co, Cu, Zn, and Cd). An epitaxially-grown surface is provided on at least one surface of the substrate. An unevenness having a height of 500 nm or more is not provided on the epitaxially-grown surface.

According to the disclosure, it is possible to provide a RAMO₄ substrate having higher quality.

### BRIEF DESCRIPTION OF THE DRAWINGS

FIG. 1 is a diagram illustrating a manufacturing processing of a conventional ScAlMgO₄ substrate.

FIG. 2A is a side view illustrating the conventional ScAlMgO₄ substrate.

FIG. 2B is a plan view illustrating the conventional ScAlMgO₄ substrate.

FIG. 3 is a diagram illustrating a result obtained by measuring flatness of a conventional epitaxially-grown surface which is formed only by cleaving.

FIG. 4 is a diagram illustrating a manufacturing process of a ScAlMgO₄ substrate according to an embodiment of the disclosure.

FIG. 5 is a diagram illustrating a result obtained by measuring flatness when a ScAlMgO₄ cleavage surface Is polished by using diamond slurry of 2 μm.

FIG. 6 is a diagram illustrating a result obtained by measuring flatness when a ScAlMgO₄ cleavage surface is polished by using diamond slurry of 0.125 μm.

FIG. 7 is a diagram illustrating a result obtained by measuring flatness when a ScAlMgO₄ cleavage surface is polished by using colloidal silica.

FIG. 8 is a diagram illustrating a result obtained by measuring flatness when a ScAlMgO₄ cleavage surface is polished by using diamond-fixed abrasive grains of 0.5 μm.

FIG. 9 is a diagram illustrating a result obtained by measuring flatness after a coarse unevenness forming process in the embodiment of the disclosure.

FIG. 10 is a diagram illustrating a result obtained by measuring flatness after a fine unevenness forming process in the embodiment of the disclosure.

FIG. 11 is a diagram illustrating a result obtained by performing AFM measurement of the ScAlMgO₄ substrate according to the embodiment in the disclosure.

FIG. 12A is a plan view illustrating a ScAlMgO₄ substrate which includes an epitaxially-grown surface having a plurality of cleavage surfaces.

FIG. 12B is a side view illustrating the ScAlMgO₄ substrate.

FIG. 13 is a diagram illustrating a force applied when an epitaxially-grown surface is formed.

FIG. 14 is a diagram illustrating a result obtained by performing AFM measurement of the ScAlMgO₄ substrate according to the embodiment in the disclosure.

FIG. 15 is an enlarged view illustrating a section of two adjacent cleavage surfaces in an X-direction.

FIG. 16 is a diagram illustrating a ScAlMgO₄ substrate which has a satin-finish shape.

FIG. 17 is a partial enlarged view illustrating a section of the ScAlMgO₄ substrate which has a satin-finish shape.

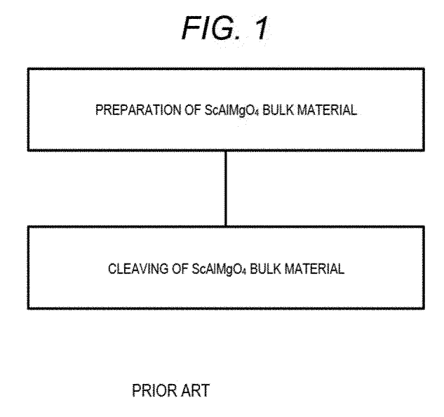

### DESCRIPTION OF EMBODIMENTS

Hereinafter, an embodiment of the disclosure will be described with reference to the drawings.

Firstly, knowledge leading to the disclosure will be described. As described in Patent Literature 1, in the related art, a ScAlMgO₄ substrate is manufactured by cleaving a ScAlMgO₄ bulk material. However, a step having a height of 500 nm or more is easily formed on an epitaxially-grown surface for growing GaN on the ScAlMgO₄ substrate, only by performing cleavage. If a step portion having a height of 500 nm or more is provided on the epitaxially-grown surface, inconvenience occurs when crystal is caused to epitaxially grow on the substrate. A disadvantage in a case where a step having a height of 500 nm or more is provided on the epitaxially-grown surface of the substrate will be described. If crystal such as GaN is produced on an epitaxially-grown surface in which a step having a height or 500 nm or more is provided, a crystal orientation at the step portion having a height of 500 nm or more is different from a crystal orientation at other portions. For example, if an InGaN layer used for an LED light emission layer is formed on an epitaxially-grown surface by a metal-organic chemical vapor deposition (MOCVD) method, the composition of indium at the step portion is different from that at a flat portion. If the composition of indium varies, emitted light wavelength and brightness when being used as an LED element are changed. As a result, light emission unevenness when being used as an LED element occurs, and deterioration of brightness is caused.

Next, details and problems of a conventional ScAlMgO₄ substrate in which a step having a height of 500 nm or more is provided will be described.

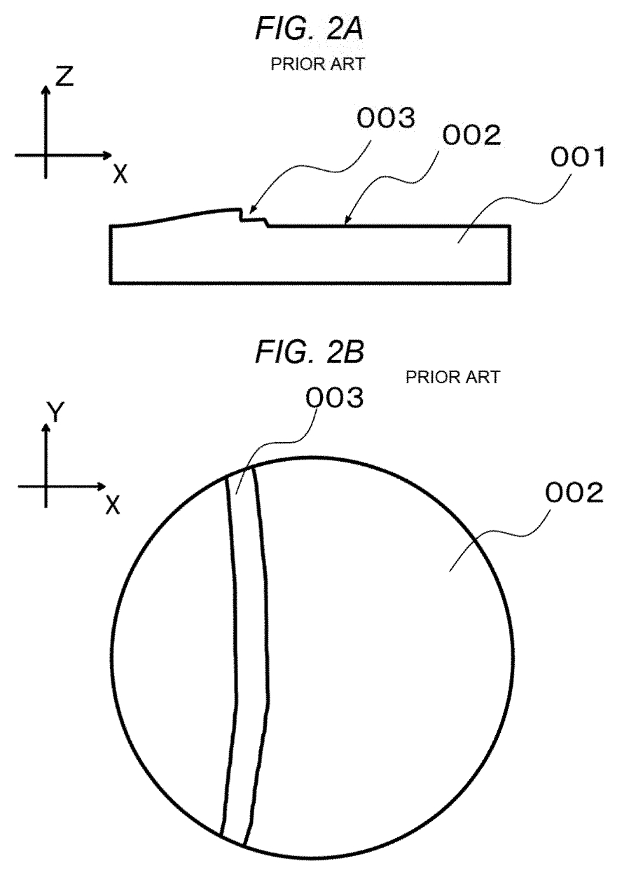

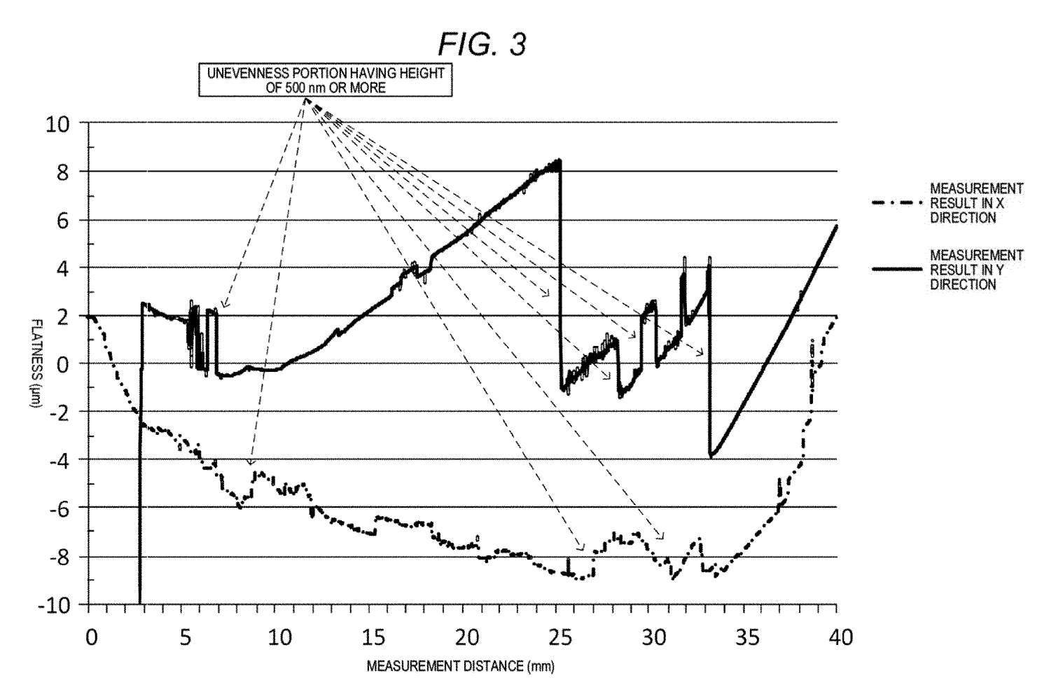

FIG. 2A is a side view illustrating conventional ScAlMgO₄ substrate 001. FIG. 2B is a plan view illustrating substrate 001. As illustrated in FIGS. 2A and 2B, step portion 003 is formed on epitaxially-grown surface 002 of ScAlMgO₄ substrate 001. Here, the height of step portion 003 is equal to or more than 500 nm. FIG. 3 illustrates data obtained by measuring flatness of epitaxially-grown surface 002 of ScAlMgO₄ substrate 001 which has been formed by cleaving. The data is obtained in such a manner that ScAlMgO₄ substrate 001 of φ40 mm is measured in X and Y axes orthogonal to each other in the same plane, by using a laser reflection type wavelength measurement device (NH-3MA manufactured by Mitaka Kohki Co., Ltd.). In FIG. 3, a portion indicated by an arrow corresponds to an unevenness portion of 500 nm or higher. It is considered that exfoliation during cleaving occurs in a cleaving direction and the force varies, and thus cleaving in the same atomic layer is not caused, and as a result, an unevenness portion formed from steps of 500 nm or higher occurs in the ScAlMgO₄ substrate.

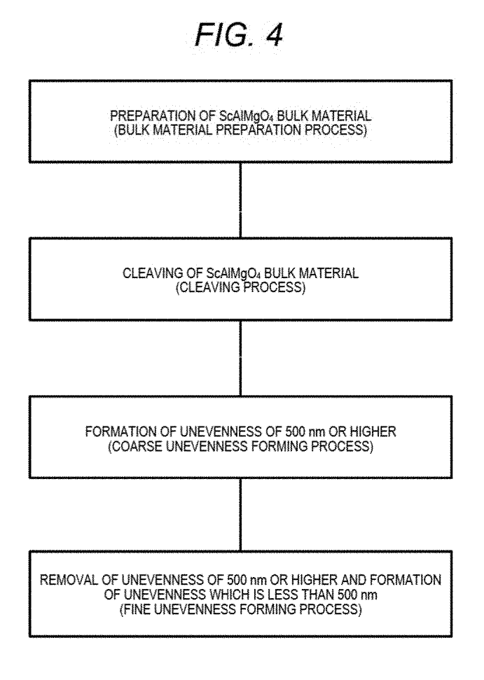

In the disclosure, a manufacturing method including a process of removing the steps having a height of 500 nm or more is provided. FIG. 4 illustrates processes of a manufacturing method of the ScAlMgO₄ substrate according to the embodiment of the disclosure. The manufacturing method according to the embodiment of the disclosure includes a process of preparing a ScAlMgO₄ bulk material (bulk material preparation process), a process of cleaving the prepared bulk material to form a substrate (cleaving process), and a process of machining a surface corresponding to an epitaxially-grown surface of the substrate (coarse unevenness forming process and fine unevenness forming process).

In the bulk material preparation process, for example, a single crystal ScAlMgO₄ ingot manufactured by using a high-frequency induction heating type Czochralski furnace is prepared. As a manufacturing method of the ingot, for example, as a starting material, Sc₂O₃, Al₂O₃, and MgO having purity of 4N (99.99%) are mixed with a predetermined molar ratio. 3400 g of the starting material is put into a crucible which is formed of iridium and has a diameter of 100 mm. Then, the crucible into which the raw material has been put is put into a growing furnace of a high-frequency induction heating type Czochralski furnace, and the inside of the furnace is vacuumed. Then, nitrogen is put into the furnace, and heating the crucible is started at a time point when pressure in the furnace reaches the atmospheric pressure. Heating is gradually performed for 12 hours until the temperature of the furnace reaches a melting point of ScAlMgO₄, and thus the material is molten. Then, ScAlMgO₄ single crystal which has been cut out at the (0001) orientation is used as seed crystal, so as to drop the seed crystal up to the near of a molten liquid in the crucible. The seed crystal is gradually dropped while being rotated at a constant rotation speed. While a tip end of the seed crystal is brought into contact with the molten liquid to gradually lower the temperature, the seed crystal is pulled up (pulled up in a [0001] axis direction) at a speed, that is, a pulling speed of 0.5 mm/h, and thus crystal growth is performed. Thus, a single crystal ingot which has a diameter of 50 mm and a straight body portion having a length of 50 mm is obtained.

Here, ScAlMgO₄ single crystal will be described. ScAlMgO₄ single crystal has a structure in which a ScO₂ layer like a (111) plane having a rocksalt structure, and an ScAlMgO₄ layer like a (0001) plane of hexagonal crystal are alternately stacked. Two layers like the (0001) plane of hexagonal crystal are flat in comparison to a wurtzite structure. Bonding between an upper layer and a lower layer has a length which is about 0.03 nm longer, and has a force weaker than those of in-plane bonding. Thus, the ScAlMgO₄ single crystal can be cleaved in the (0001) plane. The process (cleaving process) of dividing the bulk material by cleaving to prepare a ScAlMgO₄ plate may be performed by using the characteristics.

Properties relating to cleaving of the ScAlMgO₄ single crystal may cause the cleaving process to be easily performed. In contrast, machining a cleavage surface by a conventional machining method is difficult. That is, in the conventional machining method, removing an unevenness which is formed on the cleavage surface, and has a height of 500 nm or more is not possible. The reason will be described. In descriptions, generally, as an example, a case where machining performed on a semiconductor substrate such as GaN to allow an unevenness on the surface thereof to be less than 500 nm is performed on a ScAlMgO₄ substrate will be described. A machining area is set to have 10 mm angle.

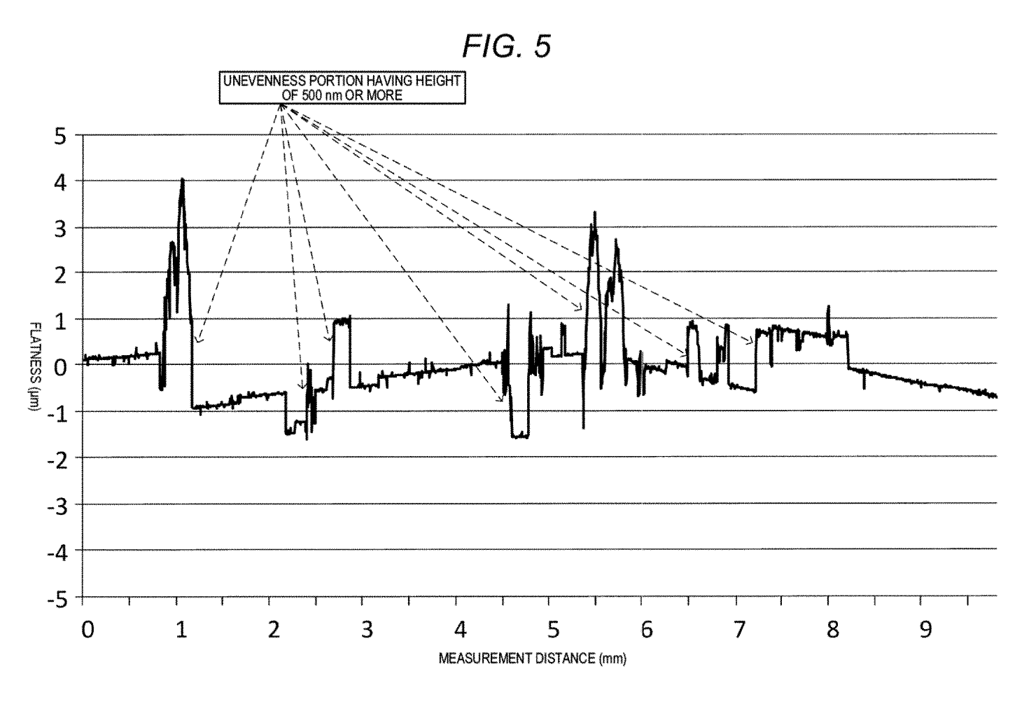

Firstly, lap polishing is performed on a cleavage surface of ScAlMgO₄ by using diamond slurry (abrasive grain). The diamond slurry has a size having a diameter of 2 μm, and is used in conventional coarse polishing. FIG. 5 illustrates a result obtained by lap polishing. FIG. 5 illustrates a result obtained in such a manner that flatness of a surface subjected to machining is measured in the X direction by the above-described laser reflection type length measurement device. As illustrated in FIG. 5, it is recognized that, if the machining is performed, an unevenness of 500 nm or higher is formed on the surface. In the lap polishing, the diamond slurry rolls on the surface of ScAlMgO₄, and thus the material at a portion at which the diamond slurry rolls is finely removed. However, the single crystal ScAlMgO₄ is a stacked body of multiple ScO₂ layers and ScAlMgO₄ layers. Thus, it is considered that variation of a machining force causes exfoliation to partially occur at a deep layer. Thus, as illustrated in FIG. 5, it is considered that an unevenness of 500 nm or higher is formed.

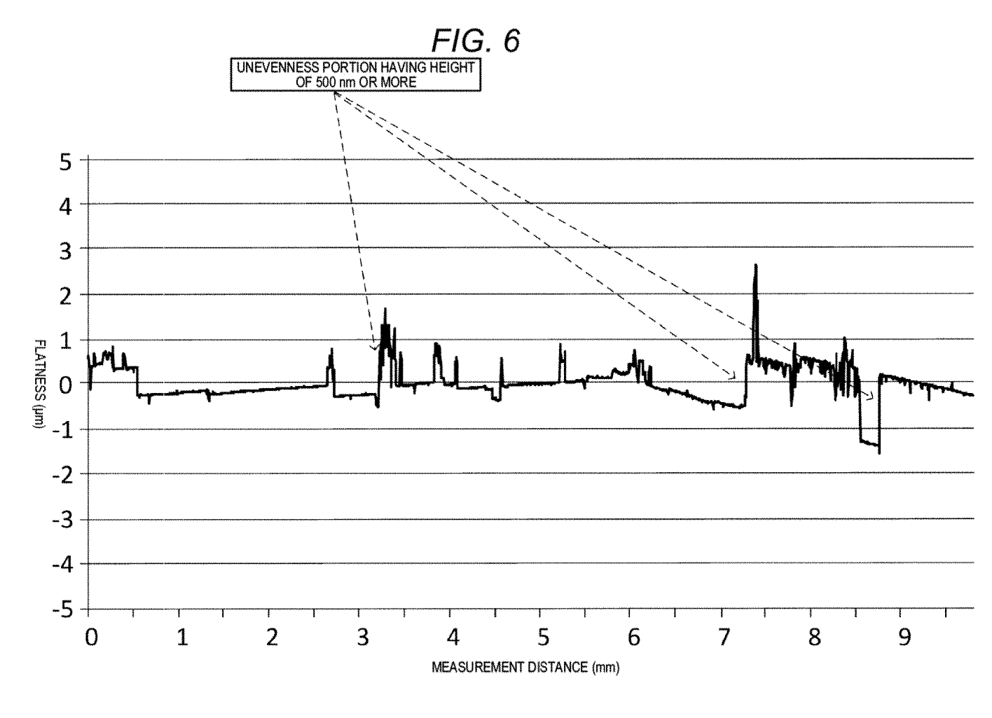

Generally, in order to reduce such variation of a machining force, it is effective to set the size of the abrasive grain to be smaller than the allowable size of the unevenness. FIG. 6 illustrates a result in a case where lap polishing is performed on the cleavage surface of ScAlMgO₄ by using diamond slurry which has a size of a diameter of 0.125 μm, as the abrasive grain. At this time, as a method of measuring flatness in the X direction, a method similar to that in a case where polishing is performed by using diamond slurry which has a size of a diameter of 2 μm is applied. As illustrated in FIG. 6, even though the size of the abrasive grain is set to be smaller than the allowable size (500 nm) of the unevenness, the unevenness having a height of 500 nm or more is formed.

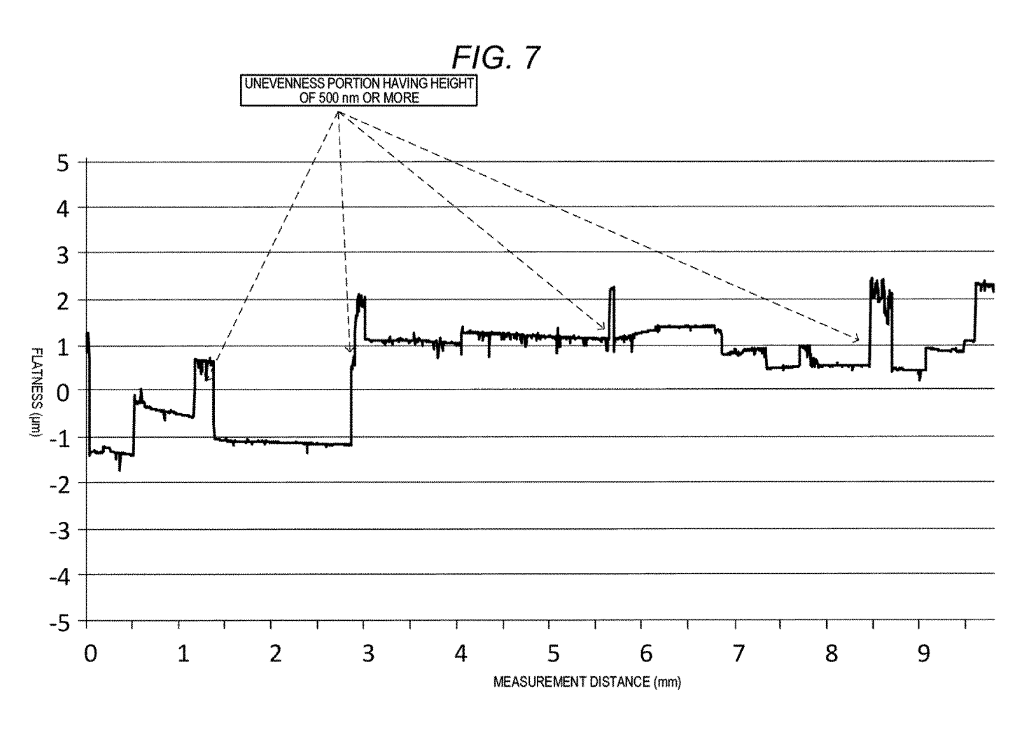

Hardness or the shape of an abrasive grain in accordance with the type of an abrasive grain also has an influence on a surface shape of the polished surface. FIG. 7 illustrates a result obtained by performing polishing with a colloidal silica abrasive grain which is softer and has a shape more approximate to a sphere, than diamond. Polishing is performed with a pressing force of 1000 Pa, when machining GaN single crystal is generally performed. At this time, as a method of measuring flatness in the X direction, a method similar to that in a case where polishing is performed by using diamond slurry which has a size of a diameter of 2 μm is applied. As illustrated in FIG. 7, according to this method, a fine unevenness can be removed, but removing an unevenness having a height of 500 nm or more is not possible.

As described above, even though polishing using any free abrasive grain is performed, causing an unevenness on an epitaxially-grown surface of a ScAlMgO₄ substrate to have a height which is less than 500 nm is not possible.

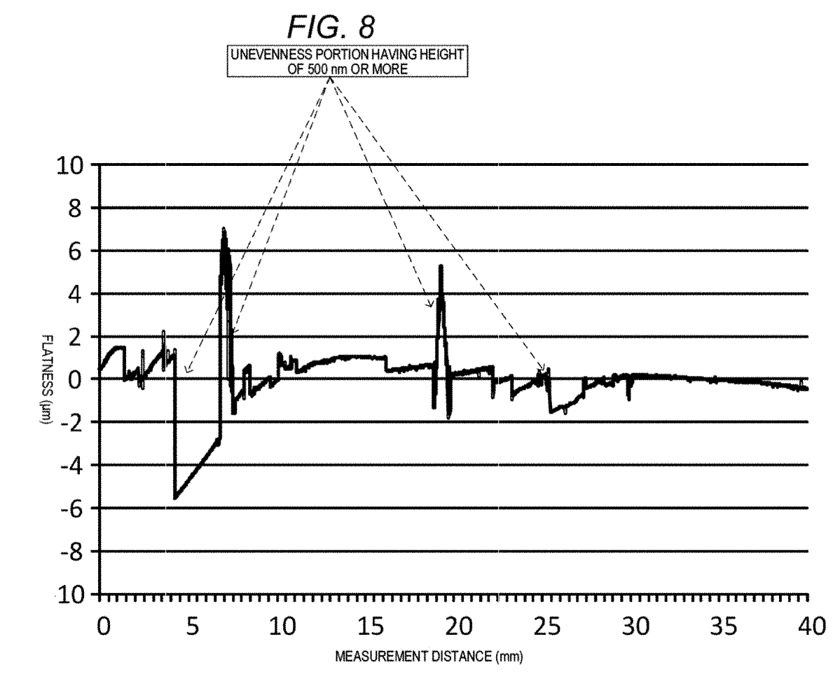

Grinding is performed by using a diamond-fixed abrasive grain which has a size of a diameter of 0.5 μm. FIG. 8 illustrates a result. As a method of measuring flatness in the X direction, a method similar to that in a case where polishing is performed by using diamond slurry which has a size of a diameter of 2 μm is applied. As illustrated in FIG. 8, an unevenness of 500 nm or higher is formed even by using a fixed abrasive grain.

It can be recognized based on the above results that machining the surface of a ScAlMgO₄ substrate to be a smooth surface which does not include an unevenness of 500 nm or higher is not possible by the conventional machining method. This means the following. That is, even though an unevenness occurring by cleaving is removed, if the proportion of an occupying flat surface to the entirety is large, machining load is easily concentrated on an area portion (unevenness) when the flat surface is machined. Thus, cracks by cleaving occur not on a surface, but in the inside deeper from the surface. Thus, it is considered that the cracked portion is removed, and thus a new unevenness is formed. In a case where the proportion of the flat surface is high, an unevenness formed in the cleaving process may be hardly removed only by applying a load which has an extent that cleaving does not occur in the inside thereof.

In the disclosure, considering features of a ScAlMgO₄ material, a machining method (coarse unevenness forming process and fine unevenness forming process) as will be described below is employed. Specifically, an unevenness shape having a constant height is formed in the entirety of a region functioning as an epitaxially-grown surface of a ScAlMgO₄ substrate (coarse unevenness forming process). Then, a pressing force is reduced in stages, and thus an unevenness shape which is formed on the entire surface and has a constant height is gradually reduced while an absolute amount of variation of the pressing force is reduced and cleaving the inside of the surface is prevented (fine unevenness forming process). That is, in the manufacturing method according to the disclosure, at least a cleaving process of cleaving ScAlMgO₄ single crystal in a (0001) plane so as to prepare a ScAlMgO₄ plate, a coarse unevenness forming process of forming an unevenness having a height of 500 nm or more, on the ScAlMgO₄ plate, and a fine unevenness forming process of polishing the unevenness having a height of 500 nm or more so as to form an unevenness having a height which is less than 500 nm are performed.

In the coarse unevenness forming process, the unevenness shape is distributed in the entire surface of a region functioning as an epitaxially-grown surface, such that any area of regions (also referred to as “a flat portion” below) is set to be equal to or smaller than 1 mm². In the flat portion, the height of the continuous unevenness is equal to or less than 500 nm. The reason is as follows. If the flat portion having an area larger than 1 mm² is formed in the coarse unevenness forming process, cleaving occurs in the inside thereof by concentration of machining load, in the fine unevenness forming process, and thus an unevenness which is higher than 500 nm is formed. It is preferable that a difference in height between a plurality of protrusions of the unevenness formed in the coarse unevenness forming process converges in a range of ±0.5 μm. An unevenness having a constant height which has variation within this range is formed on the entire surface. Thus, in the fine unevenness forming process, it is possible to gradually reduce the height of an unevenness and to form uniform flat portions in the surface.

In the manufacturing method according to the disclosure, specifically, an unevenness having a height of 500 nm or more is formed by using the first abrasive grain in the coarse unevenness forming process. Then, in the fine unevenness forming process, an unevenness having a height which is less than 500 nm is formed by using the second abrasive grain which has hardness lower than that of the first abrasive grain.

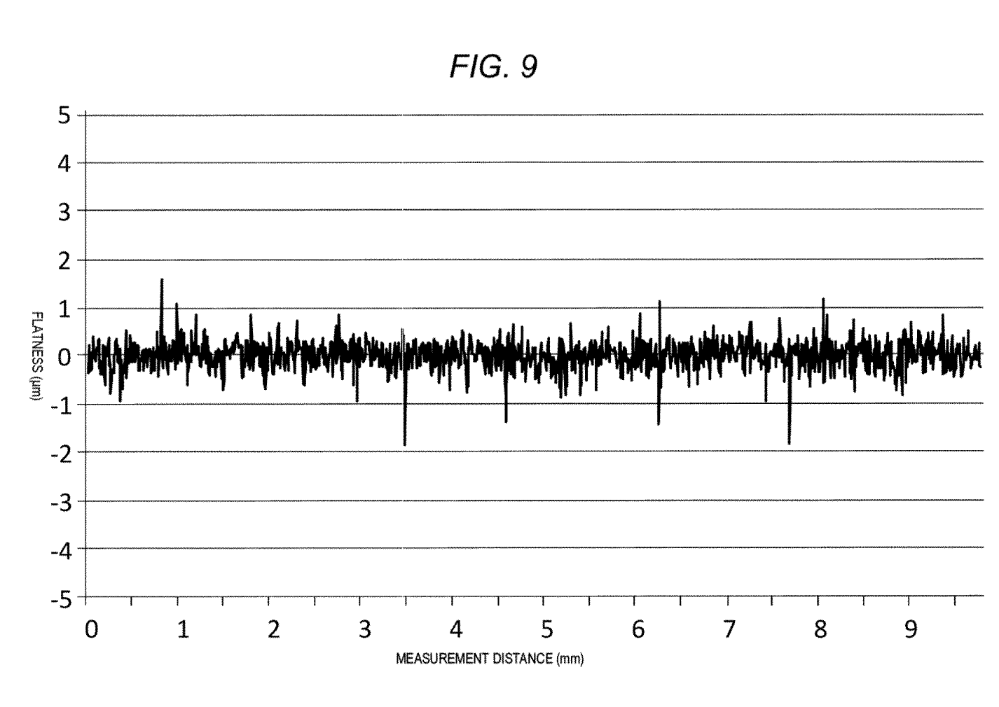

More detailed, in the unevenness forming process of machining an unevenness shape having a constant height, grinding is performed by using a diamond-fixed abrasive grain having a large abrasive grain size. As the abrasive grain, an abrasive diamond grain of #300 to #20000 (preferably #600) is used. According to machining using an abrasive diamond grain which has a size in this range, the difference in height of an unevenness on a surface subjected to machining converges in a range of ±5 μm. Machining conditions in the coarse unevenness forming process are preferably as follows. The number of rotations of a whetstone is set to be 500 min⁻¹ to 50000 min⁻¹ (preferably, 1800 min⁻¹), the number of rotations of a ScAlMgO₄ substrate is set to be 10 min⁻¹ to 300 min⁻¹ (preferably, 100 min⁻¹), the machining speed is set to be 0.01 μm/second to 1 μm/second (preferably, 0.3 μm/second), and the machining and removing amount is set to be 1 μm to 300 μm (preferably, 20 μm). FIG. 9 illustrates a result obtained by machining with an abrasive diamond grain of #600 under conditions that the number of rotations of a whetstone is 1800 min⁻¹, the number of rotations of a ScAlMgO₄ substrate is 100 min⁻¹, the machining speed is 0.3 μm/second, and the machining and removing amount is 20 μm. FIG. 9 illustrates a result obtained in a manner that flatness of a surface subjected to machining, in the X direction is measured by using a method similar to the above descriptions. As illustrated in FIG. 9, it is possible to form a regular unevenness shape, without forming a flat portion of 1 mm² or larger (site in which the area of a continuous region in which the height of an unevenness is equal to or less than 500 nm is equal to or larger than 1 mm²) in a region functioning as an epitaxially-grown surface.

Next, the fine unevenness forming process in which an unevenness formed in the coarse unevenness forming process is gradually removed will be described. In the fine unevenness forming process, an unevenness having a height which is less than 500 nm is formed in a manner that polishing is performed at a pressing force which is weakened in stages, while the unevenness having a height of 500 nm or more is removed. In the fine unevenness forming process, it is preferable that slurry in which colloidal silica is used as the main component is used as an abrasive grain, the number of rotations is 10 min⁻¹ to 1000 min⁻¹ (preferably, 60 min⁻¹), the amount of supplied slurry is 0.02 ml/minute to 2 ml/minute (preferably, 0.5 ml/minute), and a non-woven fabric pad is used as a polishing pad. In a case where many unevennesses are provided, it is easy that a machining force is selectively concentrated at protrusions. Thus, it is preferable that the pressing amount is set to be in a range of 10000 Pa to 20000 Pa for an initial time of the fine unevenness forming process, is set to be in a range of 5000 Pa or more and less than 10000 Pa while the protrusions become flat, and is finally set to be in a range of 1000 Pa or more and less than 5000 Pa. As described above, the pressing force is reduced in stages, and thus it is possible to remove an unevenness having a height of 500 nm or more, from a region functioning as an epitaxially-grown surface, without as occurrence of cleaving in the inside.

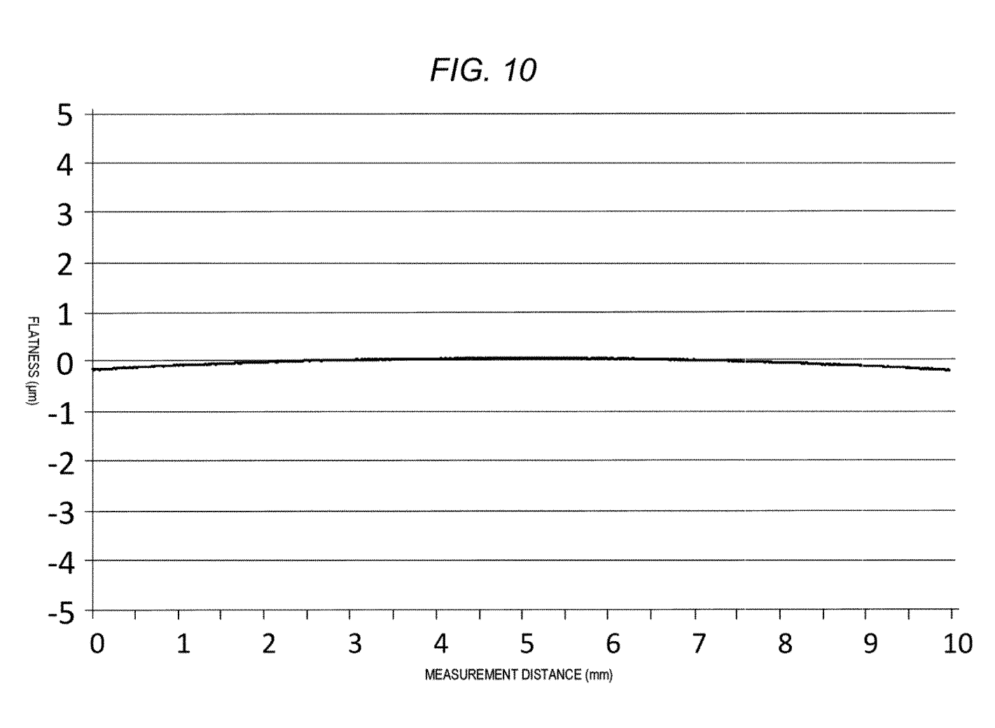

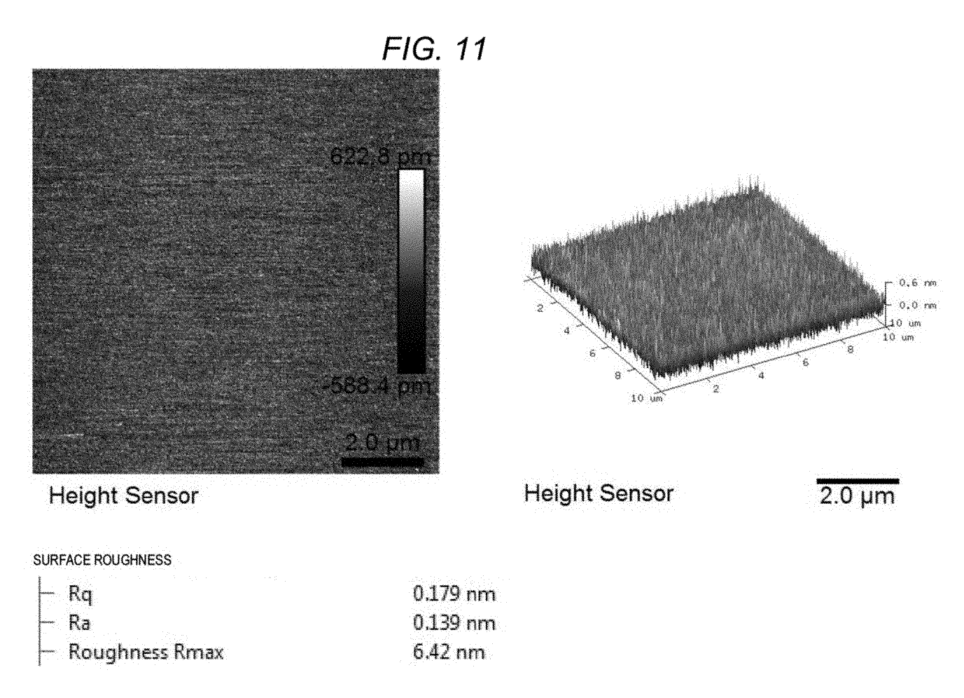

In the fine unevenness forming process, polishing is performed at 15000 Pa for three minutes, for the first time. Next, the pressing force is reduced up to 8000 Pa, and polishing is performed at 8000 Pa for five minutes. Finally, the pressing force is reduced up to 1000 Pa, and polishing is performed at 1000 Pa for 10 minutes. FIG. 10 illustrates results obtained by the above described process. FIG. 10 illustrates a surface shape measurement result obtained in a manner that flatness of an epitaxially-grown surface after machining, in the X direction is measured by using a method similar to the above descriptions. FIG 11 illustrates a surface shape measurement result obtained in a manner that a range of 10 μm angle of the epitaxially-grown surface is measured by an AFM (atomic force microscope). As illustrated in FIG. 11, an unevenness having a height of 500 nm or more is not provided in the range of 10 μm angle, and an unevenness having a height of 50 nm or more, in which Rmax indicating the maximum height is 6.42 nm is not observed. Rq is 0.179 nm. More detailed, it is understood that it is possible to form a very smooth surface in which surface roughness Ra in a small region of 100 μm² is 0.139 nm, and an unevenness of 50 nm or higher is not provided, based on FIG. 11 obtained by detailed shape analysis. The surface roughness Ra is 0.08 nm to 0.5 nm in the region of 100 μm in the ScAlMgO₄ substrate formed by the above-described method. The surface roughness Ra is a value which is measured based on ISO13565-1 by using Dimension Icon manufactured by BROKER Corporation.

In this manner, obtaining a smooth surface in which an unevenness formed by cleaving is not provided may be realized by a process as follows. Machining (coarse unevenness forming process) is performed to cause a smooth surface formed by cleaving to have an unevenness shape with intention and regularity. Then, the unevenness is removed little by little by machining in which cleaving does not occur (fine unevenness forming process). That is, according to the disclosure, a ScAlMgO₄ substrate having an epitaxially-grown surface in which the height of an unevenness is less than 500 nm, additionally, the height of an unevenness is equal to or less than 50 nm is obtained. Realizing the ScAlMgO₄ substrate is not possible by the conventional method. When surface roughness is observed, for example, in a range of 10 μm angle (100 μm²), the surface roughness Ra on the surface of the substrate obtained by the above method is 0.08 nm to 0.5 nm. In this manner, for example, in a case where an LED light emission layer is formed on the epitaxially-grown surface of this substrate, a problem in that the above-described composition varies, light emission unevenness occurs in an LED element by the variation of the composition, or brightness is degraded does not occur. Further, the height of an unevenness is equal to or less than 50 nm, and thus an occurrence of formation poorness (for example, residue by etching a step portion) by the unevenness is suppressed, for example, when an electrode is formed after an LED light emission layer has been formed on an epitaxially-grown surface. Accordingly, manufacturing yield of a device such as an LED, which is manufactured by using this substrate is improved.

Here, details of the method will be collectively described. In the coarse unevenness forming process, the unevenness of 500 nm or higher is formed by using a whetstone to which abrasive diamond grains of #300 to #2000 are attached. The unevenness is formed under the following machining conditions. The number of rotations of the whetstone is set to be 500 min⁻¹ to 50000 min⁻¹. The number of rotations of the ScAlMgO₄ plate is set to be 10 min⁻¹ to 300 min⁻¹. The machining speed is set to be 0.01 μm/second to 1 μm/second. The machining and removing amount is set to be 1 μm to 300 μm. In the fine unevenness forming process, an unevenness having a height which is less than 500 nm is formed by using slurry in which colloidal silica is contained as the main component and by using a polishing pad formed from a non-woven fabric pad. The formation is performed under the following machining conditions. The number of rotations of the polishing pad is set to be 10 min⁻¹ to 1000 min⁻¹. The amount of supplied slurry is set to be 0.02 ml/minute to 2 ml/minute. The pressing force is set to be 1000 Pa to 20000 Pa. Further, regarding the unevenness which is lower than 500 nm, it is possible to more precisely form a surface in which an unevenness of 500 nm or higher, particularly, an unevenness of 50 nm or higher is not provided, in a manner that pressing force is weakened in an order of a range of 10000 Pa to 20000 Pa, a range of 5000 Pa or more and less than 10000 Pa, and a range of 1000 Pa or more and less than 5000 Pa, while machining proceeds.

The epitaxially-grown surface may be formed only on one surface (front surface) of a ScAlMgO₄ substrate. Only the front surface is subjected to polishing, and thus it is possible to simplify the processes. In this case, the unevenness of 500 nm or higher in a state of being formed remains as it is, on the other surface (back surface). The epitaxially-grown surface may be formed on both surfaces of the ScAlMgO₄ substrate. In this case, epitaxial growth of nitride semiconductor such as GaN can be performed on both surfaces.

The epitaxially-grown surface may be configured by the above-described single (0001) plane (cleavage surface). If a portion such as a defect or a foreign substance, which functions as a seed for accidental crystal growth is provided in the epitaxially-grown surface, when vapor phase growth of GaN is performed on the epitaxially-grown surface by, for example, a MOCVD method, Ga atoms may be concentrated on the seed for accidental crystal growth, and locally-ununiform growth may occur. In order to prevent an occurrence of such a case, the epitaxially-grown surface may include a plurality of cleavage surfaces which are separated from each other by steps, and are regularly distributed. When vapor phase growth of GaN is performed on a ScAlMgO₄ substrate by, for example, a MOCVD method, the Ga raw material moves (migrates) in the (0001) plane which is a cleavage surface of the epitaxially-grown surface, in a state where a portion of the Ga raw material is bonded to a methyl group. If the position of the Ga raw material is a stable position, the Ga raw material stops at this position. A bond with a methyl group is cut off, and the Ga raw material is bonded to N, and thus epitaxial growth is performed. Accordingly, the plurality of cleavage surfaces is formed on the epitaxially-grown surface, and step portions of cleavage surfaces which are adjacent to each other are caused to have stable positions, and are utilized. Thus, epitaxial growth is stabilized. The plurality of cleavage surfaces is formed to have regularity, and thus there is an advantage in that growth is regularly performed when epitaxial growth is performed en the epitaxially-grown surface by a MOCVD method.

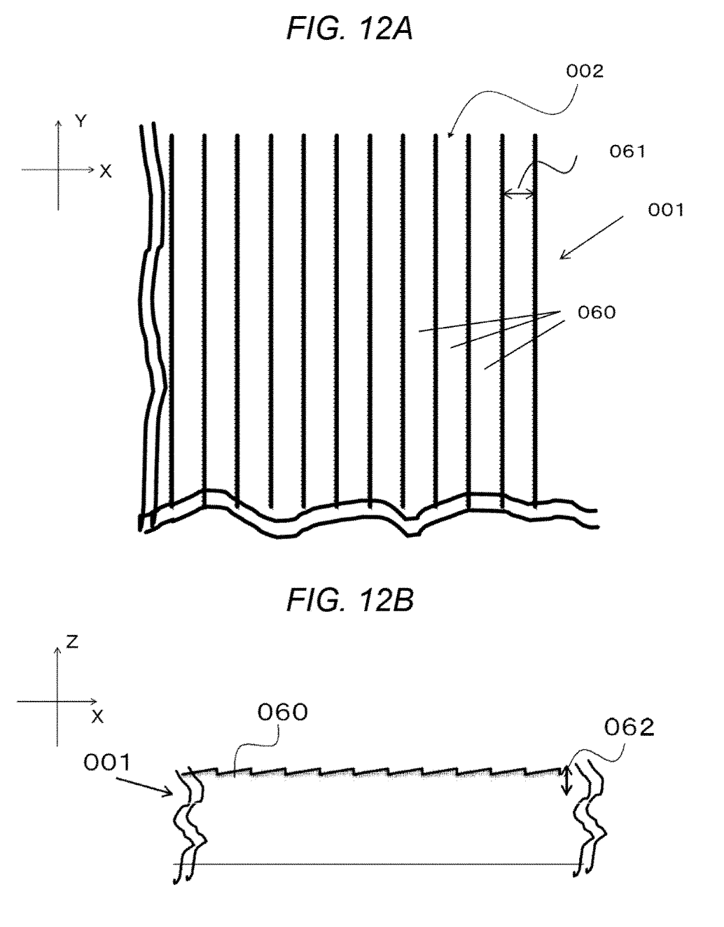

FIGS. 12A-12B illustrate a ScAlMgO₄ substrate 001 including epitaxially-grown surface 002 which includes a plurality of cleavage surfaces 060. FIG. 12A is a plan view illustrating the ScAlMgO₄ substrate. FIG. 12B is a side view illustrating the ScAlMgO₄ substrate. As illustrated in FIG. 12A, in the ScAlMgO₄ substrate, it is preferable that cleavage surface 060 has a long shape, and a plurality of cleavage surfaces 060 is regularly formed in parallel to each other. The width of cleavage surface 060 in the X direction corresponds to cleavage surface width 061, and the step height between adjacent cleavage surfaces corresponds to height 062 between cleavage surfaces.

Here, cleavage surface width 061 is preferably set to move a Ga raw material to the step portion of the cleavage surface, which is a stable position, when epitaxial growth is performed by a MOCVD method. Specifically, in a case where epitaxial growth of GaN crystal is performed by a MOCVD method, if the cleavage surface width is set to be in a range of 1.5 nm to 500 nm, it is possible to obtain a uniform epitaxial film on the entirety of the epitaxially-grown surface. The reason is as follows. If the cleavage surface width is less than 1.5 nm, a stable position of the Ga raw material when epitaxial growth is performed is significantly close to the molecule size of the raw material molecule. Thus, realizing step flow growth (growth mode in which epitaxial growth proceeds from each step portion in a horizontal direction, and a uniform epitaxial film is obtained) in which a uniform epitaxial film is obtained may be not possible. If the cleavage surface width is equal to or more than 500 nm, the cleavage surface width is much larger than a migration distance of the Ga raw material by a MOCVD method on a GaN surface (distance obtained by Ga raw material molecules moving on the epitaxially-grown surface from when the Ga raw material molecules adhere to the epitaxially-grown surface, until the Ga raw material molecules react with molecules which are an N raw material, and GaN is obtained). Thus, similarly, realizing step flow growth is not possible. Furthermore, if the cleavage surface width is set to be in a range of 5 nm to 150 nm, it is possible to form an epitaxial film in which variation of a crystal orientation is uniformly small and impurity concentration is uniformly appropriate on the entirety of the epitaxially-grown surface. The reason is as follows. In a case where the cleavage surface width is set to be in a range of 5 nm to 150 nm, the cleavage surface width coincides with the migration distance of the Ga raw material by a MOCVD method on the GaN surface. Thus, most of Ga raw material molecules adhering to the surface migrates to the step portion of the cleavage surface. Thus, step flow growth proceeds well on the entirety of the epitaxially-grown surface of the ScAlMgO₄ substrate, a crystal orientation of a base is maintained, and a uniform epitaxial film is grown.

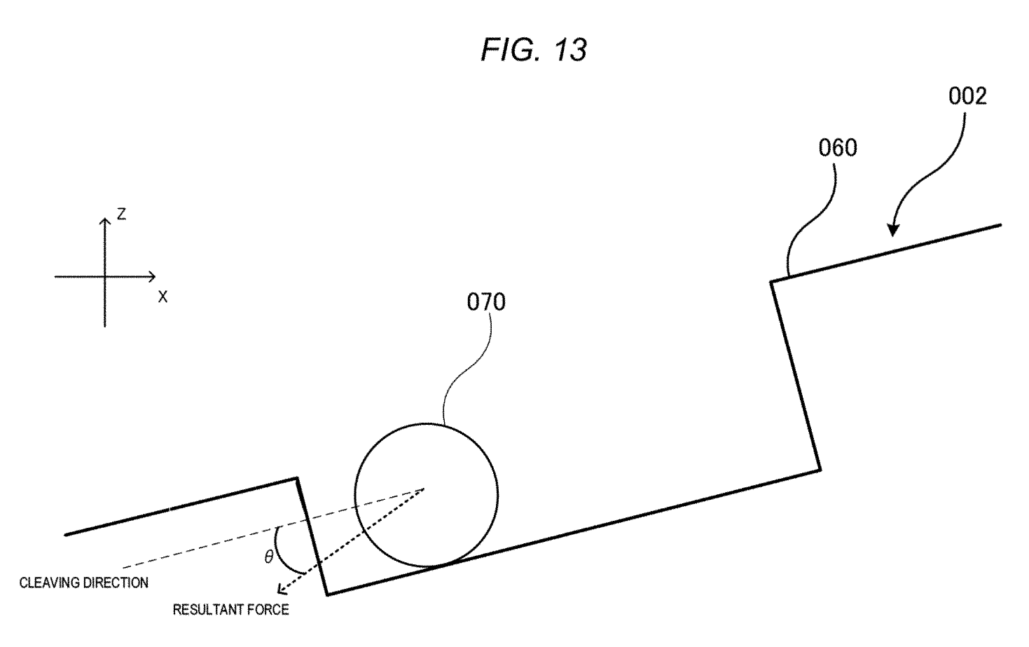

Here, a method of performing machining to set cleavage surface width 061 to be 1.5 nm to 500 nm will be described. FIG. 13 illustrates a diagram of a machining status in a case where a surface formed from a plurality of cleavage surfaces is subjected to machining. FIG. 13 is a sectional view of epitaxially-grown surface 002 in the X direction. An orientation of a force applied when machining with abrasive grain 070 is performed is an orientation of a resultant force formed from a resultant vector of a force for moving abrasive grain 070 in the X direction, and a force for moving abrasive grain 070 in a Z direction. In this case, an angle is formed between an abrasive grain moving direction, and the cleavage surface. In a case of being viewed from the entirety of epitaxially-grown surface 002, regarding a vector of a force applied to abrasive grain 070, a machining status varies depending on the size of an inclination angle. For example, machining is easily performed in a certain direction, and performing machining is difficult in a certain direction. Thus, in order not to form an unevenness on each of cleavage surfaces 060, it is necessary that the pressing force is set considering a state where an opening angle θ between a cleaving direction, and a vector direction of a force applied to the abrasive grain is large. Accordingly, it is necessary that final machining is performed in a state of pressure lower than that in a case where the cleavage surface is not divided into plural pieces. In addition, the range of the final pressing force in the fine unevenness forming process is set to be 20 Pa to 3000 Pa.

That is, in the above-described fine unevenness forming process, the plurality of cleavage surfaces can be formed by using slurry in which colloidal silica is contained as the main component and by using a polishing pad formed from a non-woven fabric pad. The formation is performed under conditions that the number of rotations of the polishing pad is set to be 10 min⁻¹ to 1000 min⁻¹, the amount of supplied slurry is set to be 0.02 ml/minute to 2 ml/minute, and the pressing force is set to be equal to or less than 20000 Pa. More detailed, in the fine unevenness forming process, the plurality of cleavage surfaces is formed at a pressing force which is sequentially weakened in an order of a range of 10000 Pa to 20000 Pa, a range of 5000 Pa or more and less than 10000 Pa, and a range of 20 Pa to 3000 Pa, while machining proceeds.

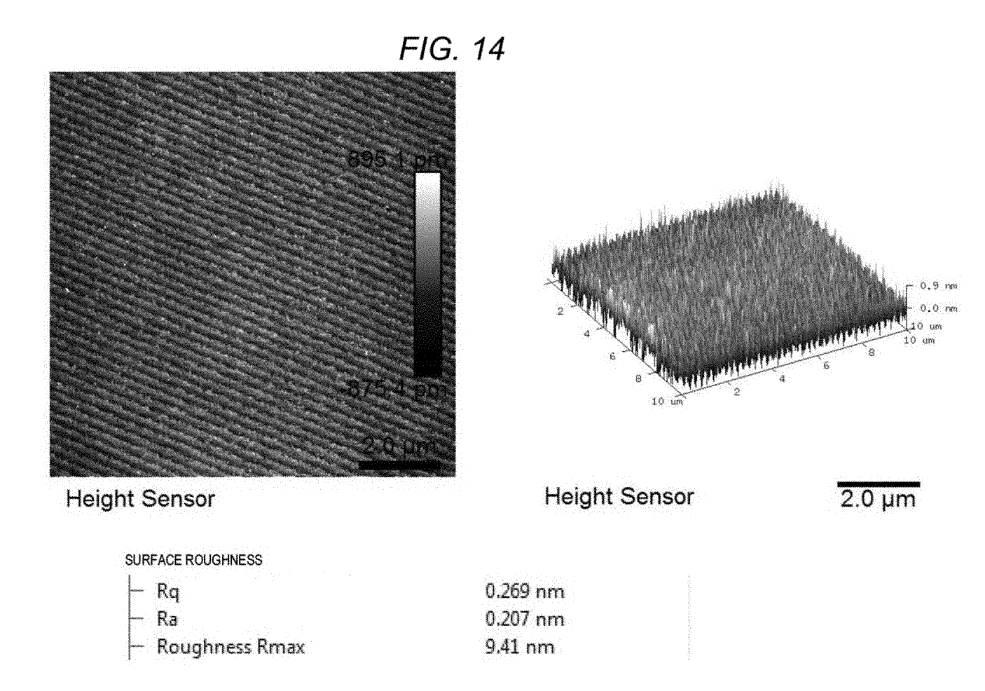

FIG. 14 illustrates a result obtained by performing polishing at the final pressing force decreased up to 200 Pa, for 10 minutes, in the fine unevenness forming process. Conditions other than the final pressing condition are the same as conditions when the ScAlMgO₄ substrate illustrated in FIG. 11 is obtained. FIG. 14 illustrates a surface shape measurement result obtained by performing measurement with an AFM in a range of 100 μm². As illustrated in FIG. 14, it is understood that epitaxially-grown surface 002 is formed from a plurality of long cleavage surfaces.

Here, the final pressing force in the fine unevenness forming process, when cleavage surface width 061 is set to be 1.5 nm to 500 nm is set to be in a range of 20 Pa to 3000 Pa. However, in a case where cleavage surface width 061 is set to be 5 nm to 150 nm, an opening angle θ between a resultant vector of the pressing force applied to the abrasive grain and a cleavage direction is reduced. Thus, the final pressing force may be set to be in a range of 100 Pa to 2800 Pa. That is, in a case where the cleavage surface width 061 is set to be 5 nm to 150 nm, in the fine unevenness forming process, the cleavage surface is formed in a manner that pressing force is weakened in an order of a range of 10000 Pa to 20000 Pa, a range of 5000 Pa or more and less than 10000 Pa, and a range of 100 Pa to 2800 Pa.

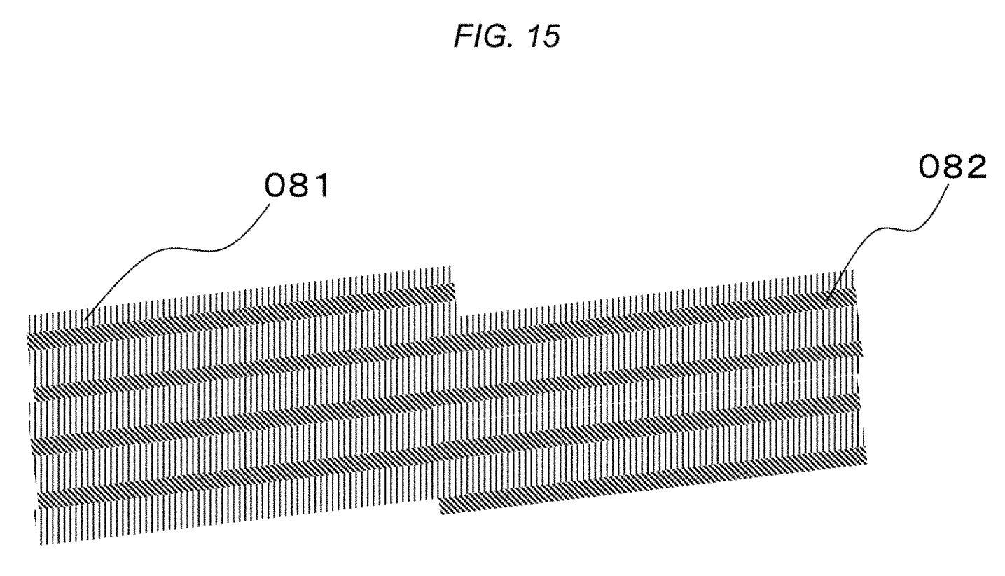

Here, height 062 between cleavage surfaces will be described. FIG. 15 illustrates an enlarged view of a section of two adjacent cleavage surfaces in the X direction. In FIG. 15, in a ScAlMgO₄ substrate formed from ScAlO₂ atomic layer 081 and ScO₂ atomic layer 082, ScO₂ atomic layer 082 is one layer, but MgAlO₂ layer 081 is obtained by stacking two layers. A portion between the layers in MgAlO₂ layer 081 functions as the cleavage surface. Thus, the outermost surface is formed by one layer of MgAlO₂ layer 081. Regarding height 062 between the cleavage surfaces, the thickness of MgAlO₂ atomic layer 081 corresponding to two layers, and ScO₂ atomic layer 082 corresponding to one layer is used as the minimum unit, in accordance with features of a cleavage portion considered from atomic arrangement of ScAlMgO₄. That is, the above-described thickness is set to be the minimum unit of height 062 between the cleavage surfaces in FIG. 12, and specifically, is about 0.8 nm.

In addition, in a case where epitaxial growth of GaN crystal is performed by using a MOCVD method, the height between cleavage surfaces is desirably equal to or less than a constant height in order to suppress epitaxial growth from a wall surface of the step portion. The wall surface of the step portion has a crystal orientation different from that of the cleavage surface. Accordingly, crystal which is epitaxially grown on the wall surface may cause problems in that impurity concentration is different or yield of epitaxial growth is reduced because this crystal is a cause of generation of polycrystal, in comparison to crystal which is epitaxially grown on the cleavage surface. Specifically, if the height between cleavage surfaces is set to be in a range of one time to ten times the minimum unit, generation of polycrystal is suppressed, and yield of epitaxial growth is improved. That is, height 062 between cleavage surfaces is preferably 0.8 nm to 8 nm. In order to form height 062 between cleavage surfaces so as to be 0.8 nm to 8 nm, machining is performed such that an epitaxially-grown surface as a result of performing machining at the final pressing force is measured in a range of 100 μm² by using an AFM, and as a result, the surface roughness Ra is 0.08 nm to 1.5 nm.

In addition, if the height between cleavage surfaces is set to be in a range of one time to four times the minimum unit, an epitaxial film in which impurity concentration is uniform in the entirety of an epitaxially-grown surface in addition to suppression of generating polycrystal is obtained well. That is, height 062 between cleavage surfaces is preferably set to be 0.8 nm to 3.2 nm. In order to form height 062 between cleavage surfaces so as to be 0.8 nm to 3.2 nm, machining is performed such that an epitaxially-grown surface as a result of performing machining at the final pressing force is measured in a range of 100 μm² by using an AFM, and as a result, the surface roughness Ra is 0.08 nm to 1.0 nm.

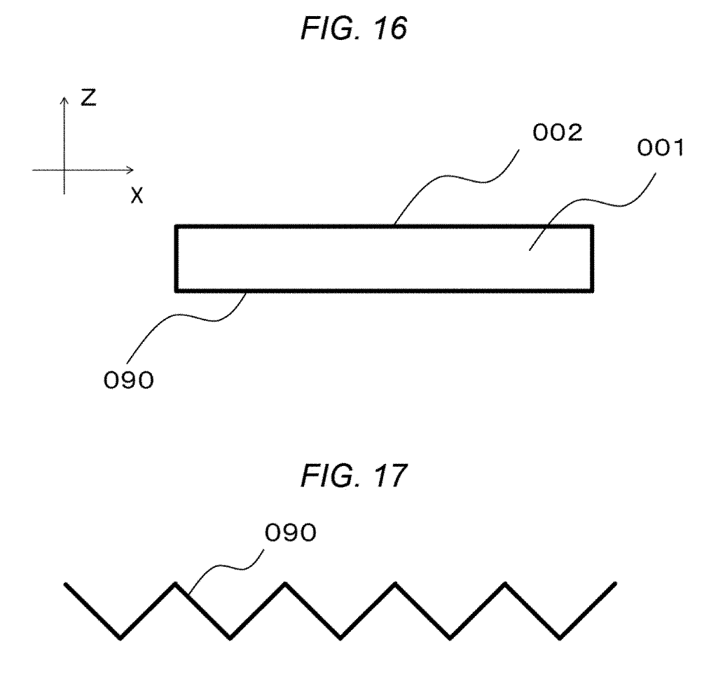

In the ScAlMgO₄ substrate according to the disclosure, as illustrated in FIG. 16, the one surface of the ScAlMgO₄ substrate, that is, the back surface of epitaxially-grown surface 002 may be satin-finish shape 090. FIG. 16 illustrates ScAlMgO₄ substrate 001 which includes satin-finish shape 090. Satin-finish shape 090 is provided on the back surface of the ScAlMgO₄ substrate, and thus the front surface and the back surface of ScAlMgO₄ substrate 001 are easily distinguished from each other. When ScAlMgO₄ substrate 001 is transported, satin-finish shape 090 functions as slip resistance. Thus, it is possible to suppress an occurrence of damage or defects by slipping and collision of ScAlMgO₄ substrate 001 during the transportation. Here, in the ScAlMgO₄ substrate according to the disclosure, satin-finish shape 090 has surface roughness Ra larger than that of epitaxially-grown surface 002. Even in a case where a plurality of cleavage surfaces 060 is formed in epitaxially-grown surface 002, the surface roughness of satin-finish shape 090 is largest. Specifically, the surface roughness Ra of epitaxially-grown surface 002 formed from a single cleavage surface is generally 0.08 nm to 0.5 nm. In a case where a plurality of cleavage surfaces is provided, the surface roughness Ra of epitaxially-grown surface 002 is generally 0.08 nm to 1.5 nm. On the contrary, the surface roughness of satin-finish shape 090 is 500 nm to 8000 nm. The surface roughness is a value measured in a region of 100 μm². FIG. 17 illustrates an enlarged view of satin-finish shape 090.

It is preferable that the height of the unevenness shape in epitaxially-grown surface 001 is equal to or less than 500 nm, but the height of the unevenness shape in satin-finish shape 090 is equal to or more than 500 nm. The height of the unevenness is a value obtained by measurement in the above-described laser reflection type measuring device. In a case where the back surface of the epitaxially-grown surface in the ScAlMgO₄ substrate does not have a satin-finish shape in which an unevenness having a height of 500 nm or more is provided, when exposure for forming a pattern having a device structure or a wiring structure on the epitaxially-grown surface side is performed, since the ScAlMgO₄ substrate is transparent, light from the back surface may be reflected, and the reflected light may influence the exposure. In addition, the following problems may occur. That is, there is a problem in that distinguishment between the front surface and the back surface is difficult in handling, and thus confusion may occur, and a problem in that slipping may easily occur when a substrate is installed on a flat surface of a manufacturing device, such as a stage.

Satin-finish shape 090 may be formed by a machining method of forming a uniform unevenness on the front surface. Specifically, satin-finish shape 090 may be formed by grinding which uses a diamond-fixed abrasive grain having a large abrasive grain size. An abrasive diamond grain of #100 to #2 000 is used as the abrasive grain. More preferably, an abrasive diamond grain of #600 is used. That is, a substrate including satin-finish shape 090 is obtained by the process of preparing a ScAlMgO₄ plate which is obtained by cleaving ScAlMgO₄ single crystal in the (0001) plane, the process of polishing one surface (front surface) of the ScAlMgO₄ plate so as to form an epitaxially-grown surface, the process of machining a surface (back surface) on an opposite side of the epitaxially-grown surface so as to form a satin-finish surface which has surface roughness larger than that of the epitaxially-grown surface. The satin-finish surface is formed by using a whetstone to which an abrasive diamond grain of #100 to #2000 is attached. The formation is performed under the following machining conditions. The number of rotations of the whetstone is 500 min⁻¹ to 50000 min⁻¹. The number of rotations of the ScAlMgO₄ plate is 10 min⁻¹ to 300 min⁻¹. The machining speed is 0.01 μm/second to 1 μm/second. The machining and removing amount is 1 μm to 300 μm. Preferably, a difference of an unevenness may be reduced by using an abrasive diamond grain of #600. Machining is performed under preferable machining conditions as follows. The number of rotations of the whetstone is 1800 min⁻¹. The number of rotations of the ScAlMgO₄ plate is 100 min⁻¹. The machining speed is 0.3 μm/second. The machining and removing amount is 20 μm.

In order to remove an influence of an affected layer by machining, grinding or blast machining for forming the affected layer may be performed.

Here, the epitaxially-grown surface is a surface on which another type of crystal is epitaxially grown on crystal functioning as a substrate. For example, the epitaxially-grown surface may be set to be a region on an inner side of 5 mm or more from an outer circumference of the substrate. Epitaxial growth is a growth form of crystal in which new crystal is aligned and arranged to a crystal surface of the substrate on the base. Crystal of a compound semiconductor such as a nitrogen compound of the III group may be grown on the epitaxially-grown surface by a vapor phase growth method such as a MOCVD method, a metal-organic vapor phase epitaxy (MOVPE) method, and a hydride phase epitaxy (HVPE) method, or a liquid phase growth method such as a flux method.

MOCVD growth of GaN is described as a method of performing epitaxial growth on the ScAlMgO₄ substrate. However, in a case of growth of AlGaInN crystal obtained by adding Al or In to GaN, similar advantages are also obtained.

The growing method is also not limited to MOCVD. Other growing methods may be used together, for example, HVPE growth or a method of performing HVPE growth after MOCVD growth. Regarding the growth temperature, an AlGaInN buffer layer may be grown at a low temperature of about 500° C. to 600° C., and then growth of GaN crystal may be performed at a high temperature of 1000° C. or higher. A light emitting device, a power device, and the like may be formed by performing hetero junction of the same AlGaInN on the AlGaInN crystal layer.

### OTHER EMBODIMENTS

In the above-described embodiment, a substrate obtained from single crystal of ScAlMgO₄ s described among substrates formed from single crystal which is represented by the formula RAMO₄. However, the disclosure is not limited thereto.

The substrate according to the disclosure is configured from a substantially single crystal material which is represented by the formula RAMO₄. In the formula, R indicates one or a plurality of trivalent elements selected from Sc, In, Y, and a lanthanoid element (atomic number 66 to 71). A indicates one or a plurality of trivalent elements selected from Fe(III), Ga, and Al. M indicates one or a plurality of bivalent elements selected from Mg, Mn, Fe(II), Co, Cu, Zn, and Gd. The substantially single crystal material refers to crystalline solid, for example, which contains RAMO₄ constituting an epitaxially-grown surface, so as to be equal to or more than 90 at %, and an orientation of any portion of the epitaxially-grown surface is the same when focusing on a certain crystal axis. However, a matter in which an orientation of a crystal axis locally varies, or a matter which includes a localized lattice defect is also handled as single crystal. O indicates oxygen. As described above, it is desirable that R is set to be Sc, A is set to be Al, and M is set to be Mg.

When an LED element in which an LED light emission layer is grown on a substrate during MOCVD vapor phase growth is manufactured, a substrate according to the disclosure is used, and thus an occurrence of light emission unevenness and degradation of brightness as an LED element may be prevented.

What is claimed is:

1. A RAMO₄ substrate comprising a single crystal represented by a formula of RAMO₄ (in the formula, R indicates one or a plurality of trivalent elements selected from a group consisting of Sc, In, Y, and a lanthanoid element, A indicates one or a plurality of trivalent elements selected from a group consisting of Fe(III), Ga, and Al, and M indicates one or a plurality of bivalent elements selected from a group consisting of Mg, Mn, Fe(II), Co, Cu, Zn, and Cd), wherein
an epitaxially-grown surface is provided on at least one surface of the RAMO₄ substrate, and
an unevenness having a height of 500 nm or more is not provided on the epitaxially-grown surface.

2. The RAMO₄ substrate of claim 1, wherein
the epitaxially-grown surface is a region on an inside which is equal to or more than 5 mm from an outer circumference of the RAMO₄ substrate.

3. The RAMO₄ substrate of claim 1, wherein
the epitaxially-grown surface does not include an unevenness having a height of 50 nm or more.

4. The RAMO₄ substrate of claim 1, wherein
surface roughness Ra in a region of 100 μm² in the epitaxially-grown surface is at least 0.08 nm and no greater than 0.5 nm.

5. The RAMO₄ substrate of claim 1, wherein
the epitaxially-grown surface is provided on one surface of the RAMO₄ substrate, and
an unevenness having a height of at least 500 nm is provided on another surface.

6. The RAMO₄ substrate of claim 1, wherein
the epitaxially-grown surface is provided on both surfaces of the RAMO₄ substrate.

7. The RAMO₄ substrate of claim 1, wherein
in the formula, R indicates Sc, A indicates Al, and M indicates Mg.

8. A manufacturing method of a RAMO₄ substrate, the method comprising:
a cleaving process of cleaving single crystal represented by a formula of RAMO₄ (in the formula, R indicates one or a plurality of trivalent elements selected from a group consisting of Sc, In, Y, and a lanthanoid element, A indicates one or a plurality of trivalent elements selected from a group consisting of Fe(III), Ga, and Al, and M indicates one or a plurality of bivalent elements selected from a group consisting of Mg, Mn, Fe(II), Co, Cu, Zn, and Cd) in a (0001) plane so as to prepare a RAMO₄ plate;
a coarse unevenness forming process of forming an unevenness in the RAMO₄ plate to have a height of 500 nm or more; and
a fine unevenness forming process of polishing the unevenness having a height of 500 nm or more to form an unevenness having a height which is less than 500 nm.

9. The manufacturing method of a RAMO₄ substrate of claim 8, wherein
the coarse unevenness forming process is a process of forming the unevenness having a height which is less than 500 nm, by using a first abrasive grain, and
the fine unevenness forming process is a process of polishing the unevenness having a height of 500 nm or more, by using a second abrasive grain which has hardness lower than that of the first abrasive grain to form the unevenness having a height which is less than 500 nm.

10. The manufacturing method of a RAMO₄ substrate of claim 8, wherein
in the fine unevenness forming process, a pressing force during polishing is weekend in stages, so as to polish the unevenness having a height of 500 nm or more, and to form the unevenness having a height which is less than 500 nm.

11. The manufacturing method of a RAMO₄ substrate of claim 8, wherein
in the coarse unevenness forming process,
grinding is performed by using a whetstone to which an abrasive diamond grain of #300 to #2000 is attached, under conditions that the number of rotations of the whetstone is 500 min⁻¹ to 50000 min⁻¹, the number of rotations of the RAMO₄ plate is 10 min⁻¹ to 300 min⁻¹, a machining speed is 0.01 μm/second to 1 μpm/second, and a machining and removing amount is 1 μm to 300 μm, and
in the fine unevenness forming process polishing is performed by using a polishing pad which is formed from slurry having colloidal silica as a main component, and a non-woven fabric, under conditions that the number of rotations of the polishing pad is 10 min⁻¹ to 1000 min⁻¹, an amount of supplied slurry is 0.02 ml/minute to 2 ml/minute, and a pressing force is 1000 Pa to 20000 Pa.

12. The manufacturing method of a RAMO₄ substrate of claim 10, wherein
in the fine unevenness forming process, the pressing force is gradually weakened in an order of a range of 10000 Pa to 20000 Pa, a range of 5000 Pa or more and less than 10000 Pa, and a range of 1000 Pa or more and less than 5000 Pa.

13. The manufacturing method of a RAMO₄ substrate of claim 8, wherein
in the formula, R indicates Sc, A indicates Al, and M indicates Mg.
